(19) United States
(12) Patent Application Publication
(10) Pub. No.: US 2007/0296499 A1
(43) Pub. Date: Dec. 27, 2007

(54) AMPLIFIER CIRCUIT HAVING A COMPENSATION CIRCUIT COUPLED TO AN OUTPUT NODE OF AN OPERATIONAL AMPLIFIER FOR IMPROVING LOOP STABILITY

(76) Inventors: Ming-Huang Liu, Yunghe City (TW); Kai-Ming Liu, Zhubei City (TW); Chen-Hsien Han, Kao-Hsiung City (TW); Meng-Yong Lin, Taipei City (TW); Sung-En Liu, Hsin-Chu City (TW); Chi-Mo Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/423,449

(22) Filed: Jun. 11, 2006

(51) Int. Cl. H03F 3/45

(52) U.S. Cl. 330/255

(57) ABSTRACT

An amplifier circuit includes an operational amplifier and a compensation circuit. The operational amplifier includes an amplifying stage for amplifying an input signal to generate an amplifying signal; and an output stage coupled to an output node of the amplifying stage for receiving the amplifying signal and generating an output signal according to the amplifying signal. The compensation circuit is coupled to the output stage and the amplifying stage for generating a compensation signal according to the output signal, and feeding the compensation signal back to the output node of the amplifying stage for compensating the amplifying signal.

### BACKGROUND OF THE INVENTION

1. Field of the Invention

The invention relates to an amplifier circuit, and more particularly, to an amplifier circuit having a compensation circuit coupled to an output node of an operational amplifying for improving loop stability.

2. Description of the Prior Art

The operational amplifier has been applied extensively in the field of electrical devices and electronics, such as the inverter amplifier, the integrator, and the filter circuit, to name just a few instances. Generally, the operational amplifier applied in the conventional drive chip is normally a two-stage amplifier that includes a first stage amplifier circuit (amplifying stage) and a second stage output circuit (output stage). The first stage amplifier circuit of the conventional operational amplifier is utilized for enhancing the gain of the operational amplifier; and the second stage output circuit is utilized for driving the capacitive or resistively loading of the operational amplifier. However, the conventional operational amplifier has one problem of insufficient loop stability. There are two methods in the related art for making improvements: one is utilizing a miller compensation circuit, and the other is utilizing the pole-zero tracking circuit.

Please refer to FIG. 1. FIG. 1 is a circuit diagram of the operational amplifier 100 applied in the miller compensation mechanism. The operational amplifier 100 primarily includes a first stage amplifier circuit (amplifying stage) 110 for amplifying an input signal (i.e., vᵢₙₚ and vᵢₙₘ) and a second stage output circuit (output stage) 120 for generating an output signal Vₒᵤₜ. Meanwhile, the first stage amplifier circuit 110 includes a plurality of transistors M1 through M13, and the second output circuit 120 includes a plurality of transistors M14 through M15. The voltage v_{bn1} and v_{bn2} actuate the transistors M1 and M2 and determine the size of the bias current; the transistors M3 and M4 are utilized for receiving the input signal (i.e., vᵢₙₚ and vᵢₙₘ); the voltage v_{bp1} and v_{bp2} actuate the transistors M5, M6, M9 and M10 to be a loading circuit; and the voltage v_{bp3} and v_{bn3} control the transistors M12 and M13 for deciding the static current of the second output circuit 120. Please note that, the internal structure of the conventional operational amplifier 100 is considered well-known to those of average skill in the pertinent art and further details are therefore hereinafter omitted for the sake of brevity. The conventional operational amplifier 100 not only includes a first stage amplifier circuit 110 and a second stage output circuit 120, but also couples to a compensation unit 130 between the output node of the first stage amplifier circuit 110 and the output node of the second stage output circuit 120. The compensation unit 130 is a miller compensation capacitance that is composed of a transistor M16. The compensation unit 130 can perform pole-splitting to the output signal of the first stage amplifier circuit 110 and the second stage output circuit 120 for the purpose of achieving stable operation. However, while the loading range of the operational amplifier 100 is too large, the cost of the compensation mechanism will also be too high.

Please refer to FIG. 2. FIG. 2 is a circuit diagram of the operational amplifier 200 applied in a pole-zero tracking mechanism. Comparing with FIG. 1 and FIG. 2, the operational amplifier 200 provides an extra tracking unit 240 in the second stage output circuit 120. Meanwhile, the tracking unit 240 is composed of a transistor M17. The operational amplifier 200 utilizes the transistor M17 for detecting the current and transconductance of the transistor M15 in the second stage output circuit 120 to track the pole-changing of the second stage output circuit 120. Moreover, the operational amplifier 200 collocates the compensation circuit 230 for generating an extra zero point and two complex poles. However, although the compensation technology, specifically, by utilizing the pole-zero tracking, is able to better resist higher loading changes, its capabilities are not unlimited.

Conclusively, in the environment of the drive chip application, the loading may be the distributed resistors and capacitors loading and simply capacitors loading. However, both the above-mentioned two conventional compensation methods do not easily make these two loading situations stable at the same time, and further limit the utilizing conditions and application field of the traditional operational amplifier. Therefore, it is important to find methods and devices to effectively improve the loop stability. This has become the key issue in the designing of the operational amplifier.

### SUMMARY OF THE INVENTION

It is therefore one of the many objectives of the claimed invention to provide an amplifier circuit having a compensation circuit for improving loop stability to solve the above-mentioned problems.

According to the present invention, an amplifier circuit is disclosed. The amplifier circuit includes an operational amplifier and a compensation circuit. The operational amplifier includes an amplifying stage for amplifying an input signal to generate an amplifying signal; and an output stage coupled to an output node of the amplifying stage for receiving the amplifying signal and generating an output signal according to the amplifying signal. The compensation circuit is coupled to the output stage and the amplifying stage for generating a compensation signal according to the output signal, and feeding the compensation signal back to the output node of the amplifying stage for compensating the amplifying signal.

The amplifier circuit of the present invention relates to a compensation circuit coupled to an output node of an operational amplifier. The compensation circuit generates a voltage-controlled current according to the input voltage of the operational amplifier and feedback the voltage-controlled current to the output node of the first stage amplifier circuit of the operational amplifier. Therefore, the amplifier circuits not only greatly reduces the phase delay of unity-gain frequency of the operational amplifier by the feedback of the voltage-controlled current, but also increases the phase margin of the operational amplifier and further widely improve the loop stability of the entire system by providing a zero point.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of an operational amplifier applied in the miller compensation mechanism.

FIG. 2 is a circuit diagram of an operational amplifier applied in the pole-zero tracking mechanism.

FIG. 3 is a circuit diagram of an amplifier circuit according to an embodiment of the present invention.

FIG. 4 is the equivalent circuit diagram of the compensation circuit shown in FIG. 3.

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

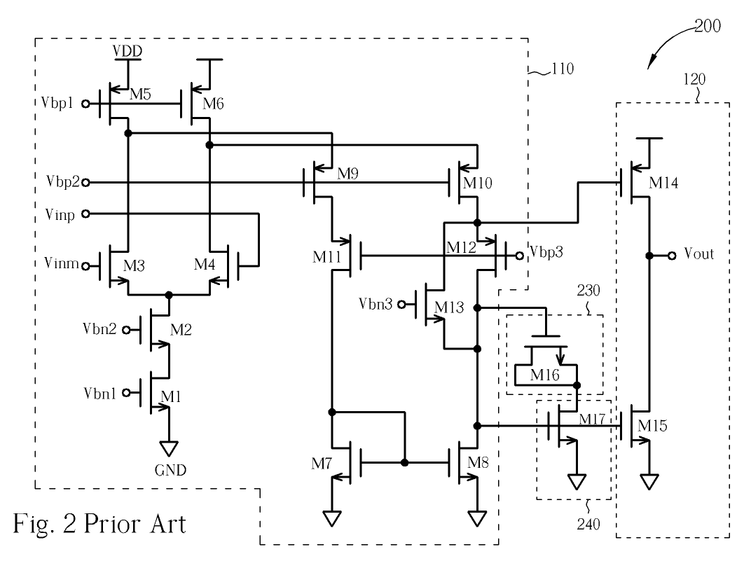

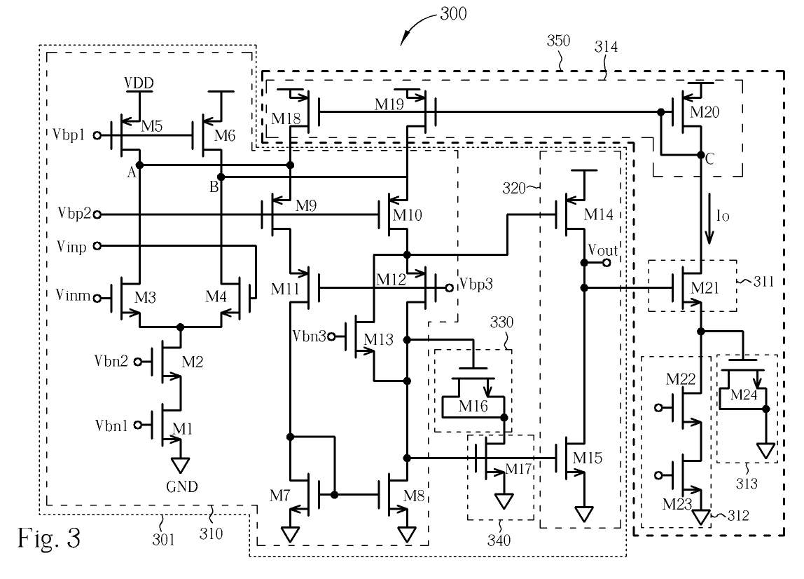

Please refer to FIG. 3. FIG. 3 is a circuit diagram of an amplifier circuit 300 according to an embodiment of the present invention. The amplifier circuit 300 includes an operational amplifier 301 and a compensation circuit 350. The operational amplifier 301 primarily includes a first stage amplifier circuit 310 and a second stage output circuit 320. The first stage amplifier circuit 310 includes a plurality of transistors M1 through M3, and the second stage output circuit 320 includes a plurality of transistors M14 through M15. In addition, in this preferred embodiment, the operational amplifier 301 applies the transistors M16 and M17 respectively to compose a compensation unit 330 and a tracking unit 340. Since the circuit structure of operational amplifier 301 is as same as the circuit structure of the conventional operational amplifier 200 shown in FIG. 2, detailed description is omitted for the sake of brevity. As shown in the FIG. 3, the compensation circuit 350 includes a controllable current source 311, an impedance unit 312, a capacitance unit 313, and a current mirror circuit 314. In this preferred embodiment, the controllable current source 311 is composed of the transistor M21; the impedance unit 312 is composed of the transistors M22 and M23; the capacitance unit 313 is composed of the transistor M24; and the current mirror circuit 314 is composed of the transistors M18 through M20. As shown in FIG. 3, the current source 311, the impedance unit 312, and the capacitance unit 313 can generate a voltage-controlled current Io that contains the zero point input. On the other hand, the gate node of the transistor M21 of the controllable current source 311 is coupled to the output node of the operational amplifier 301. That is, the compensation circuit 350 in the present invention can determine the voltage-controlled current Io by utilizing the output voltage Vout of the operational amplifier 301. Then the compensation circuit feedback the voltage control current Io through the transistors M18 through M20 of the current mirror circuit 314 to the output node of the first stage circuit 310 of the operational amplifier 301 (i.e., the output node A and B shown in FIG. 3), In this case, the purpose of decreasing phase delay of unity-gain frequency of the operational amplifier 301 can be achieved.

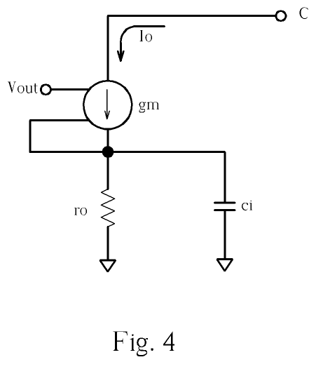

In order to further illustrate the operation of the embodiments in the present invention, please refer to FIG. 4 and FIG. 3 simultaneously. FIG. 4 is the equivalent circuit diagram of the compensation circuit 350 shown in FIG. 3. In FIG. 4, gm is related to the transconductance of the transistor M21; ro is related to the equivalent output impedance of the current bias composed from the transistors M22 and M23; and ci is related to the capacitance composed from the transistor M24 to the ground. The relationship between the voltage-controlled current Io through the transistor M20 and the output voltage Vout of the operational amplifier 301 can be expressed as follows:

$$\frac{Io}{Vout} = \frac{gm \cdot ( 1 + s \cdot ro \cdot ci )}{( gm \cdot ro + 1 ) + ( 1 + \frac{s \cdot ro \cdot ci}{gm \cdot ro + 1} )} \qquad Formula 1$$

As shown in Formula 1, while

$$s = \frac{1}{ro \cdot ci}$$

relates to a zero output; and while

$$s = \frac{gm \cdot ro + 1}{ro \cdot ci}$$

relates to a pole output. If (gm*ro+1) is large enough, the pole in the Formula 1 will be far higher than the zero point so that the pole can be neglected. That is, by appropriately selecting the parameter of every transistors of the compensation circuit 350, it can offer the operational amplifier 301 an extra zero point for increasing more phase margin. In practice, the method of utilizing the compensation circuit 350 to compensate the operational amplifier 301 can improve at lease ten degree of phase margin of the entire system. On the other hand, in this preferred embodiment, by utilizing the current mirror mechanism, the compensation circuit 350 also can feedback the voltage control current Io through the transistors M17 through M20 to the high impedance output node A and B of the first stage amplifier circuit 110 of the operational amplifier 100. In this case, the phase delay of unity-gain frequency can be significantly reduced.

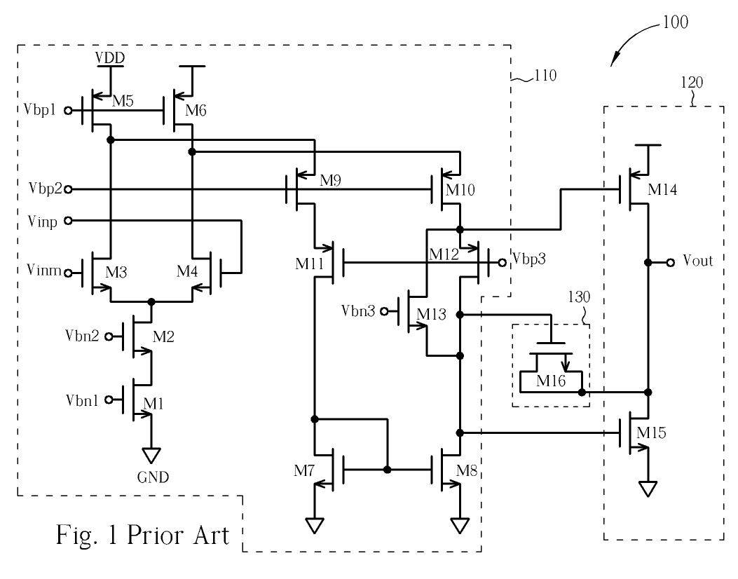

Please note that, in the above-mentioned embodiment, the controllable current source 311 is composed of the N-type Metal Oxide Semiconductor (NMOS) M21; the impedance unit 312 is composed of the N-type Metal Oxide Semiconductor (NMOS) M22 and M23; the capacitance unit 313 is composed of the N-type Metal Oxide Semiconductor (NMOS) M24; and the current mirror circuit 314 is composed of P-type Metal Oxide Semiconductor (PMOS) M17 through M20. However, the present invention does not limit to the components of the above-mentioned circuit units. That is, all electron elements, which are capable of providing the needed function of the circuit unit, also belong to the claimed invention. For example, in other embodiment, the controllable current source 311 also can be practiced by utilizing other electronic device (e.g., P-type Metal Oxide Semiconductor); the impedance unit 312 can be practiced by the single transistor or the single resistance; and the capacitance unit 313 also can be practiced by a capacitance. The present invention can change the internal structure and according to the design requirement, but the basic themes is constant. Additionally, the compensation circuit not only can co-operate with the operational amplifier with the above-mentioned conventional miller compensation mechanism or the pole-zero tracking mechanism (as shown in FIG. 1 and FIG. 2), but also can practice alone in the general operational amplifier. That is, no matter the operational amplifier has any compensate method in advance or not, the compensate circuit of the present invention can achieve the objective of improving the loop stability of the operational amplifier.

In contrast to the related art amplifier circuit, the amplifier circuit of the present invention relates to a compensation circuit coupled to an output node of an operational amplifier. The compensation circuit generates a voltage-controlled current according to the input voltage of the operational amplifier and feedback the voltage-controlled current to the output node of the first stage amplifier circuit of the operational amplifier. Therefore, the amplifier circuits not only greatly reduces the phase delay of unity-gain frequency of the operational amplifier by the feedback of the voltage-controlled current, but also increases the phase margin of the operational amplifier and further widely improve the loop stability of the whole system by providing a zero point.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplifier circuit, comprising:
an operational amplifier, comprising:
an amplifying stage for amplifying an input signal to generate an amplifying signal; and
an output stage, coupled to an output node of the amplifying stage, for receiving the amplifying signal and generating an output signal according to the amplifying signal; and
a compensation circuit, coupled to the output stage and the amplifying stage, for generating a compensation signal according to the output signal, and feeding the compensation signal back to the output node of the amplifying stage for compensating the amplifying signal.

2. The amplifier circuit of claim 1, wherein the compensation circuit comprises:
a controllable current source, wherein a control node of the controllable current source is coupled to an output node of the output stage, and a first node of the controllable current source is coupled to a output node of the amplifying stage;
an impedance unit, wherein a node of the impedance unit is coupled to a second node of the controllable current source, and another node of the impedance unit is coupled to a predetermined voltage level; and
a capacitance unit, wherein a node of the capacitance unit is coupled to the second node of the controllable current source and another node of the capacitance unit is coupled to the predetermined voltage level;
wherein the controllable current source determines the compensation signal according to the output signal from the output node of the output stage, the impedance value of the impedance unit, and the capacitance value of the capacitance unit.

3. The amplifier circuit of claim 2, wherein the controllable current source is a transistor, and the gate node of the transistor is the control node, the source node of the transistor is the second node, and the drain node of the transistor is the first node.

4. The amplifier circuit of claim 2, wherein the impedance unit is composed of at least a transistor.

5. The amplifier circuit of claim 2, wherein the capacitance unit is composed of at least a transistor.

6. The amplifier circuit of claim 2, wherein the compensation circuit further comprises:
a current mirror circuit, coupled to the first node of the controllable current source and the output node of the amplifying stage, for feeding the compensation signal provided by the controllable current source back to the output node of the amplifying stage.
